(19) United States
(12) Patent Application Publication
(10) Pub. No.: US 2011/0127673 A1
(43) Pub. Date: Jun. 2, 2011

(54) WIRING STRUCTURE AND METHOD

(75) Inventors: Felix P. Anderson, Colchester, VT (US); Thomas L. McDevitt, Underhill, VT (US); Anthony K. Stamper, Williston, VT (US)

(73) Assignee: International Business Machines Corporation, Armonk, NY (US)

(21) Appl. No.: 12/628,481

(22) Filed: Dec. 1, 2009

(51) Int. Cl. H01L 23/532; H01L 21/768

(52) U.S. Cl. 257/751; 438/653; 257/E23.161; 257/E21.584

(57) ABSTRACT

Disclosed is an improved integrated circuit wiring structure configured to prevent migration of wiring metal ions (e.g., copper (Cu+) ions in the case of a copper interconnect scheme) onto the surface of an interlayer dielectric material at an interface between the interlayer dielectric material and an insulating cap layer. Specifically, the top surfaces of wires and the top surface of a dielectric layer within which the wires sit are not co-planar. Thus, the interfaces between the wires and an insulating cap layer and between the dielectric layer and the same insulating cap layer are also not co-planar. Such a configuration physically prevents migration of wiring metal ions from the top surface of the wires onto the top surface of the dielectric layer at the interface between the dielectric layer and cap layer and, thereby prevents time dependent dielectric breakdown (TDDB) and eventual device failure. Also disclosed herein are embodiments of a method of a forming such an integrated circuit wiring structure.

### BACKGROUND

1. Field of the Invention

The embodiments of the invention generally relate to wiring structures for integrated circuits and, more specifically, to an improved integrated circuit wiring structure and method of forming the wiring structure so as to avoid time dependent dielectric breakdown (TDDB).

2. Description of the Related Art

As operational voltages and interconnect wiring densities increase with advances in integrated circuit technologies, time dependent dielectric breakdown (TDDB) has become a major concern. Specifically, during integrated circuit operation, electric fields are created between adjacent wires. Increases in operational voltages and decreases in the distance between adjacent wires have resulted in increasingly higher electric fields between adjacent wires. Over time these high electric fields can result in migration of metal ions (e.g., copper (Cu+) ions in the case of a copper interconnect scheme) across an interlayer dielectric material. Such migration in turn results in time dependent dielectric breakdown (TDDB) and eventual device failure.

### SUMMARY

In view of the foregoing, disclosed herein are embodiments of an improved integrated circuit wiring structure configured to prevent migration of wiring metal ions (e.g., copper (Cu+) ions in the case of a copper interconnect scheme) at an interface between an interlayer dielectric material and an insulating cap material. Specifically, the top surfaces of wires and the top surface of a dielectric layer within which the wires sit are not co-planar. Thus, the interfaces between the wires and a conformal insulating cap layer and between the dielectric layer and the same cap layer are also not co-planar. Such a configuration physically prevents migration of wiring metal ions from the top surface of the wires onto the top surface of the dielectric layer at the interface between the dielectric layer and cap layer and, thereby prevents time dependent dielectric breakdown (TDDB) and eventual device failure. Also disclosed herein are embodiments of a method of a forming such an integrated circuit wiring structure.

More particularly, disclosed herein are embodiments of an integrated circuit wiring structure. The wiring structure can comprise a dielectric layer. A trench can extend vertically into the dielectric layer from a top surface of the dielectric layer. A metal layer can be positioned in the trench. An insulating cap layer can be positioned on both the top surface of the dielectric layer and the top surface of the metal layer. Migration of metal ions from the top surface of the metal layer onto the adjacent top surface of the dielectric layer (i.e., across the interface between the top surface of the dielectric layer and the insulating cap layer) is prevented as a function of the difference in height between the top surface of the metal layer and the top surface of the dielectric layer.

Specifically, the metal layer can either over-fill or under-fill the trench such that the top surface of the metal layer is not co-planar with the adjacent top surface of the dielectric layer, thereby creating a physical barrier to migration of metal ions. For example, relative to the bottom surface of the trench, the top surface of the dielectric layer can be below the top surface of the metal layer. Thus, a vertical surface of the cap layer physically prevents metal ion migration from the top surface of the metal layer onto the adjacent top surface of the dielectric layer at an interface between the dielectric layer and the cap layer. Alternatively, relative to the bottom surface of the trench, the top surface of the dielectric layer can be above the top surface of the metal layer. Thus, a vertical surface of the dielectric layer physically prevents metal ion migration from the top surface of the metal layer onto the adjacent top surface of the dielectric layer at an interface between the dielectric layer and the cap layer.

Also disclosed herein are embodiments of a method of forming the above-described integrated circuit wiring structure. Specifically, the method embodiments can comprise forming a trench extending vertically into a dielectric layer from a top surface of the dielectric layer. Next, a metal layer can be formed in the trench such that the top surface of the metal layer is not co-planar with the top surface of the dielectric layer. Then, an insulating cap layer can be formed such that it is positioned on both the top surface of the dielectric layer and the top surface of the metal layer.

The above-mentioned process of forming the metal layer on the bottom surface of the trench such that the top surface of the metal layer is not co-planar with the top surface of the dielectric layer can be accomplished using any suitable technique. In one exemplary embodiment, this process can be accomplished by forming a metal layer on the dielectric layer such that it fills the trench and further such that it extends over the top surface of the dielectric layer. The metal layer can then be planarized such that it is removed from the top surface of the dielectric layer and remains only in the trench, leaving the top surface of the metal layer co-planar with the top surface of the dielectric layer. Then, either the dielectric layer or the metal layer can be selectively recessed. Specifically, the dielectric layer can be selectively recessed such that the top surface of the dielectric layer is below the top surface of the metal layer. As a result of this process, a vertical surface on the cap layer in the wiring structure will physically prevent metal ion migration from the top surface of the metal layer onto the adjacent top surface of the dielectric layer at an interface between the dielectric layer and the cap layer. Alternatively, the metal layer can be selectively recessed such that the top surface of the dielectric layer is above a top surface of the metal layer. As a result of this process, a vertical surface on the dielectric layer in the wiring structure will physically prevent metal ion migration from the top surface of the metal layer onto the adjacent top surface of the dielectric layer at an interface between the dielectric layer and the cap layer.

### BRIEF DESCRIPTION OF THE SEVERAL VIEWS OF THE DRAWINGS

The embodiments of the invention will be better understood from the following detailed description with reference to the drawings, which are not necessarily drawing to scale and in which:

FIG. 1 is a cross-section diagram illustrating a wiring structure;

FIG. 2 is a cross-section diagram illustrating another wiring structure;

FIG. 3 is a flow diagram illustrating a method of forming the wiring structure of FIGS. 1 and 2;

FIG. 4 is a cross-section diagram illustrating a partially completed wiring structure formed according to the method of FIG. 3;

FIG. 5 is a cross-section diagram illustrating a partially completed wiring structure formed according to the method of FIG. 3;

FIG. 6 is a cross-section diagram illustrating a partially completed wiring structure formed according to the method of FIG. 3;

FIG. 7 is a cross-section diagram illustrating a partially completed wiring structure formed according to the method of FIG. 3;

FIG. 8 is a cross-section diagram illustrating a partially completed wiring structure formed according to the method of FIG. 3;

FIG. 9 is a cross-section diagram illustrating a partially completed wiring structure formed according to the method of FIG. 3;

FIG. 10 is a cross-section diagram illustrating a partially completed wiring structure formed according to the method of FIG. 3;

FIG. 11 is a cross-section diagram illustrating a partially completed wiring structure formed according to the method of FIG. 3; and

FIG. 12 is a cross-section diagram illustrating a prior art wiring structure.

### DETAILED DESCRIPTION

The embodiments of the invention and the various features and advantageous details thereof are explained more fully with reference to the non-limiting embodiments that are illustrated in the accompanying drawings and detailed in the following description.

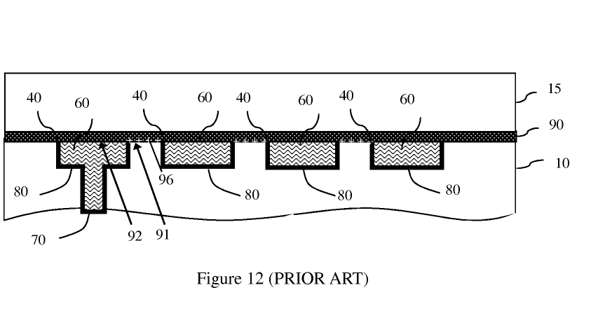

As mentioned above, as operational voltages and interconnect wiring densities increase with advances in integrated circuit technologies, time dependent dielectric breakdown (TDDB) has become a major concern. Specifically, during integrated circuit operation, electric fields are created between adjacent wires. Increases in operational voltages and decreases in the distance between adjacent wires have resulted in increasingly higher electric fields between adjacent wires. Over time these high electric fields can result in migration of metal ions across interlayer dielectric material. For example, FIG. 12 illustrates a conventional copper (Cu) wiring scheme in which wires 80 and connecting vias 70 comprise copper (Cu) layer 60-filled trenches within a dielectric layer 10 (e.g., a silicon dioxide layer). The top surface 92 of the copper (Cu) layer 60 that fills each trench is co-planar with the top surface 91 of the dielectric layer 10. An additional dielectric layer 15 (e.g., another silicon dioxide layer) above the dielectric layer 10 isolates the wires 80. Diffusion of copper (Cu) ions from copper (Cu) layer 60 into the dielectric layers 10 and 15 is prevented by a conductive diffusion barrier layer 40 lining the trenches and also by an insulating cap layer 90 (e.g., a silicon nitride (SiN) layer) between the wires 80 and the dielectric layer 15. However, with such a wiring scheme, a high operational voltage can result in a relatively high electric field between adjacent wires 80 and can, thereby cause migration of copper (Cu) ions 96 from the top surface 92 of the copper (Cu) layer 60 onto the top surface 91 of the dielectric layer 10 at the interface between the dielectric layer 10 and cap layer 90. Such migration results in time dependent dielectric breakdown (TDDB) and eventual device failure.

In view of the foregoing, disclosed herein are embodiments of an improved integrated circuit wiring structure configured to prevent migration of wiring metal ions (e.g., copper (Cu+) ions in the case of a copper interconnect scheme) at the interface between an interlayer dielectric material and an insulating cap material. Specifically, the top surfaces of wires and the top surface of a dielectric layer within which the wires sit are not co-planar. Thus, the interfaces between the wires and an insulating cap layer and between the dielectric layer and the same cap layer are also not co-planar. Such a configuration physically prevents migration of wiring metal ions from the top surface of the wires onto the top surface of the dielectric layer at the interface between the dielectric layer and cap layer and, thereby prevents time dependent dielectric breakdown (TDDB) and eventual device failure. Also disclosed herein are embodiments of a method of a forming such an integrated circuit wiring structure.

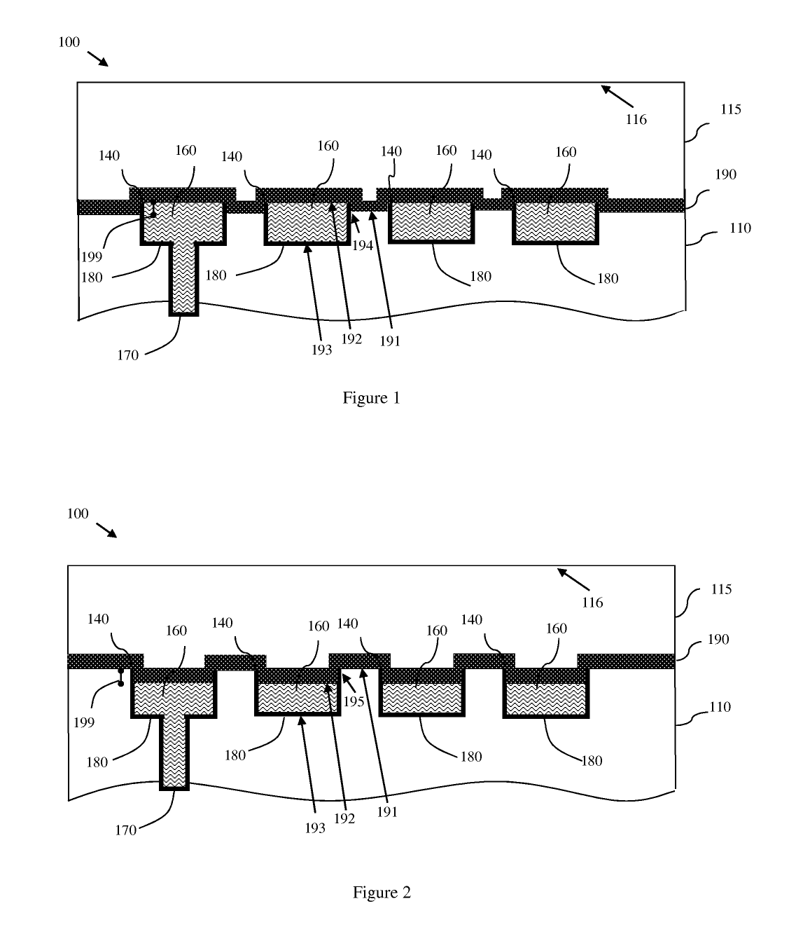

More particularly, referring to FIGS. 1 and 2, disclosed herein are embodiments of an integrated circuit wiring structure 100. The wiring structure 100 can comprise a dielectric layer 110. This dielectric layer 110 can, for example, comprise a silicon dioxide (SiO₂) layer or any other suitable interlayer dielectric material. The dielectric layer 110 can have a thickness ranging, for example, from 5000-20,000 Angstroms.

Wires 180 can be embedded in the dielectric layer 110 and connecting vias 170 can connect such wires 180 to lower wiring levels and/or device levels (not shown). Each wire 180 can comprise a trench that extends vertically into the dielectric layer 110 from a top surface 191 of the dielectric layer 110. Each trench can be lined with a thin conductive diffusion barrier layer 140. This conductive diffusion barrier layer 140 can comprise any suitable conductive material that exhibits high atomic diffusion resistance (i.e., a conductive diffusion barrier material that exhibits low atomic diffusivity) and can have a thickness ranging, for example, from 200 to 2000 Angstroms. For example, the diffusion barrier layer 140 can comprise a cobalt layer, a chromium layer, a ruthenium layer, a tantalum layer, a tantalum nitride layer, an indium oxide layer, a tungsten layer, a tungsten nitride layer, a titanium layer, a titanium nitride layer, etc. A wiring metal layer 160 (e.g., copper (Cu), aluminum (Al) or any other suitable metal or metal alloy wiring layer) can be positioned on the diffusion barrier layer 140 on the bottom surface 193 of the trench. The wiring metal layer 160 can have a thickness ranging, for example, from 2000-10,000 Angstroms and can, preferably, have a thickness of approximately 3000 Angstroms.

An insulating cap layer 190 can be positioned across the dielectric layer 110 and wires 180 (i.e., above the metal layer 160). This insulating cap layer 190 can comprise a relatively thin (e.g., 200-2000 Angstrom) conformal insulating cap layer. This insulating cap layer 190 can further comprise a different dielectric material than that used for the dielectric layer 110 and, specifically, can comprise any suitable insulating material that exhibits high atomic diffusion resistance (i.e., an insulating diffusion barrier material that exhibits low atomic diffusivity). For example, the insulating cap layer 190 can comprise a silicon nitride layer, a silicon oxynitride layer, a silicon carbide layer, a silicon carbon oxide layer, etc.

A second dielectric layer 115 can be positioned above the cap layer 190. This second dielectric layer can comprise either the same interlayer dielectric material as the first dielectric layer 110 (e.g., a silicon dioxide (SiO₂) layer) or a different interlayer dielectric material.

Migration of metal ions from the top surface 192 of a metal layer 160 (i.e., the top surface of a wire 180) onto the adjacent top surface 191 of the dielectric layer 110 (i.e., at the interface between the dielectric layer 110 and the insulating cap layer 190) is prevented as a function of the difference in height between the top surface 192 of the metal layer 160 and the top surface 191 of the dielectric layer 110 (e.g., relative to the bottom surface 193). This difference in height 199 between the top surface 191 of the dielectric layer 110 and the top surface 192 of the metal layer 190 can be, for example, between approximately 10% and 30% the thickness of the metal layer 190 and, preferably, approximately 20% the thickness of the metal layer 190. Thus, if the metal layer 190 has a thickness of approximately 3000 Angstroms, the difference in height 199 between the top surface 191 of the dielectric layer 110 and the top surface 192 of the metal layer 190 can be between 300 and 1000 Angstroms and, preferably, about 600 Angstroms.

Specifically, in each wire 180, the metal layer 160 can either over-fill or under-fill the trench such that the top surface 192 of the metal layer 160 is not co-planar with the adjacent top surface 191 of the dielectric layer 110, thereby creating a physical barrier to migration of metal ions across the interface between the dielectric layer 110 and insulating cap layer 190. For example, relative to the bottom surface 193 of the trench, the top surface 191 of the dielectric layer 110 can be below the top surface 192 of the metal layer 160. Again, as mentioned above, the difference in height 199 between the top surfaces 191 and 192 can be between approximately 10% and 30% the thickness of the metal layer 190. Thus, if the metal layer 190 has a thickness of approximately 3000 Angstroms, the top surface 191 of the dielectric layer can approximately 300 to 1000 Angstroms below the top surface 192 of the metal layer 160. Thus, a vertical surface 194 of the cap layer 190 physically prevents metal ion migration from the top surface 192 of the metal layer 160 onto the adjacent top surface 191 of the dielectric layer 110 at an interface between the dielectric layer 110 and the cap layer 190. Alternatively, relative to the bottom surface 193 of the trench, the top surface 191 of the dielectric layer 110 can be above the top surface 191 of the metal layer 160. Again, as mentioned above, the difference in height 199 between the top surfaces 191 and 192 can be between approximately 10% and 30% the thickness of the metal layer 190. Thus, if the metal layer 190 has a thickness of approximately 3000 Angstroms, the top surface 191 of the dielectric layer can approximately 300 to 1000 Angstroms above the top surface 192 of the metal layer 110. Thus, a vertical surface 195 of the dielectric layer 110 physically prevents metal ion migration from the top surface 192 of the metal layer 160 onto the adjacent top surface 191 of the dielectric layer 110 at an interface between the dielectric layer 110 and the cap layer 190.

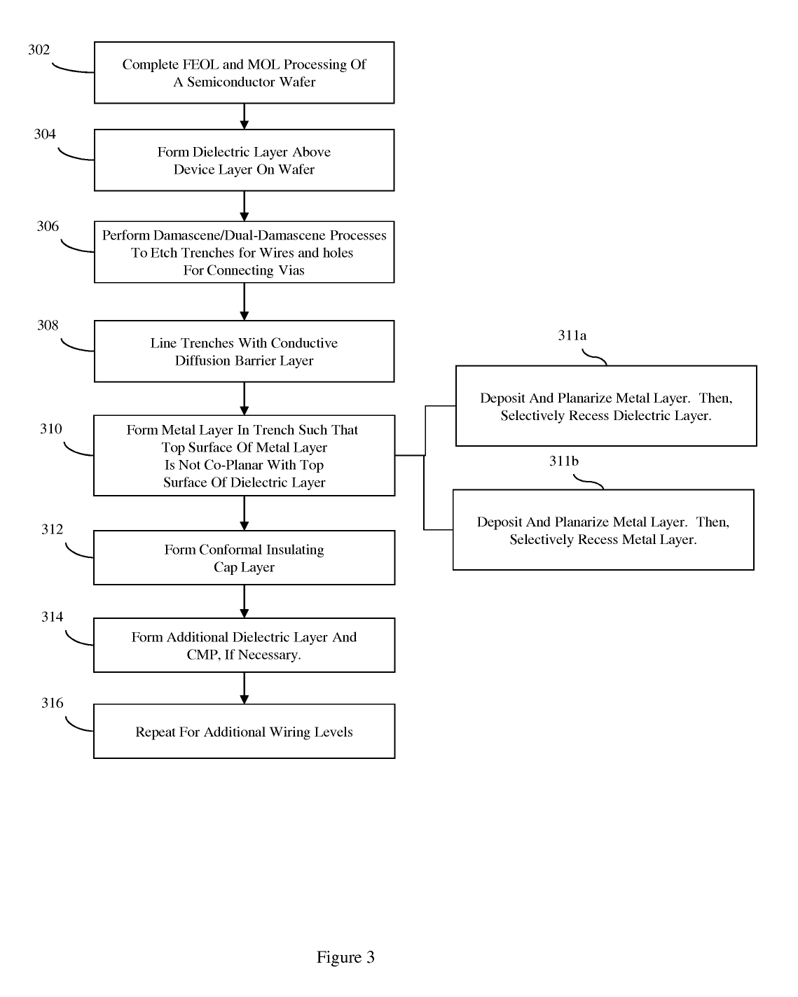

Referring to FIG. 3, also disclosed herein are embodiments of a method of forming an integrated circuit wiring structure, as described above and shown in FIGS. 1 and 2. Specifically, the method embodiments can comprise completing front end of the line (FEOL) and middle of the line (MOL) processing for integrated circuit formation on a semiconductor wafer (302). Such FEOL and MOL process steps are well-known in the art and, thus, are omitted from this specification in order to allow the reader to focus on the salient aspects of the embodiments described herein.

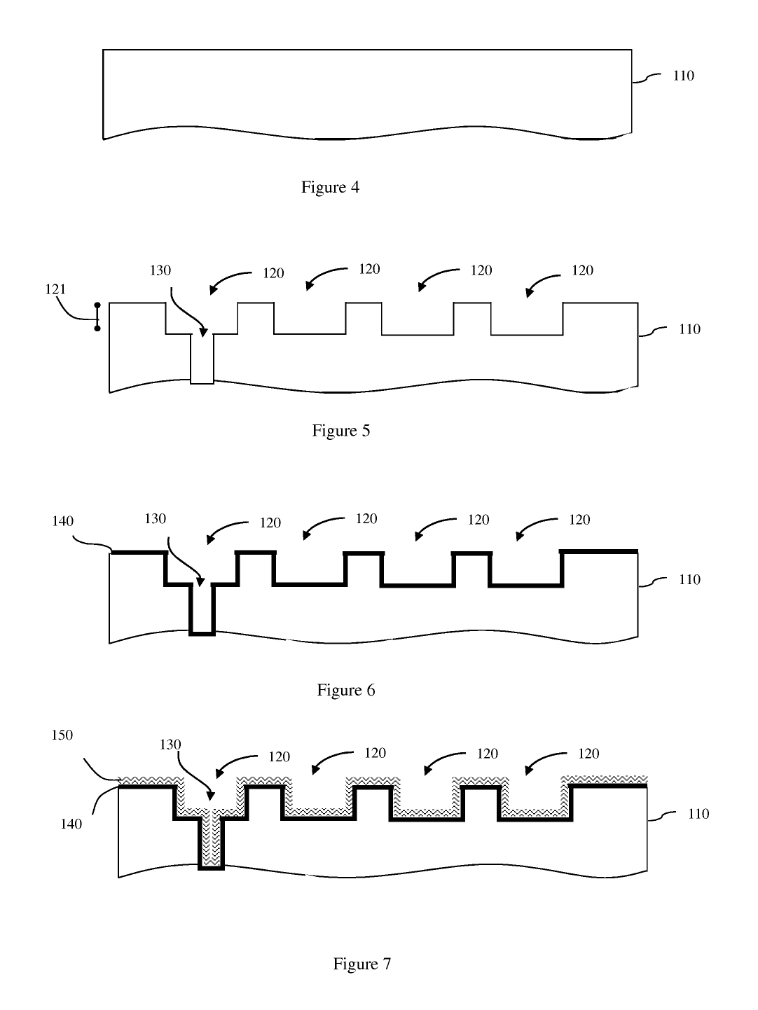

Next, a dielectric layer 110 is formed (e.g., deposited by physical vapor deposition (PVD), chemical vapor deposition (CVP), spin coating, or other suitable technique) on the wafer above a device layer (304, see FIG. 4). This dielectric layer 110 can, for example, comprise a silicon dioxide (SiO₂) layer or any other suitable interlayer dielectric material and can be deposited such that it has a thickness ranging, for example, from 5000-20,000 Angstroms.

Then, damascene and/or dual-damascene techniques are used to form trenches 120 (i.e., wiring grooves) that extend vertically a predetermined distance 121 into the dielectric layer 110 from the top surface of the dielectric layer 110 and to further to etch holes 130 for connecting vias that extend to a lower wiring layer or device layer (not shown) (306, see FIG. 5). Such damascene and dual-damascene techniques are well-known in the art and, thus, are omitted from this specification in order to allow the reader to focus on the salient aspects of the embodiments described herein. The etch depth of the trenches 120 can be predetermined based on the desired thickness of the resulting wires (e.g., between 2000-10,000 Angstroms).

Once the trenches 120 and holes 130 are formed, they can be lined (e.g., conformally or directionally) with a conductive diffusion barrier layer 140 (308, see FIG. 6). That is, any suitable conductive material that exhibits high atomic diffusion resistance (i.e., a conductive diffusion barrier material that exhibits low atomic diffusivity) can be deposited, using conventional deposition techniques (e.g., physical vapor deposition (PVD), chemical vapor deposition (CVP), or other suitable technique) onto the bottom surface and sidewalls of the trenches 120 and holes 130. Such a conductive diffusion barrier layer 140 can have a thickness ranging, for example, from 200-2000 Angstroms and can comprise a cobalt layer, a chromium layer, a ruthenium layer, a tantalum layer, a tantalum nitride layer, an indium oxide layer, a tungsten layer, a tungsten nitride layer, a titanium layer, a titanium nitride layer, etc.

Next, a metal layer 160 (e.g., a copper (Cu) layer, an aluminum (Al) layer or any other suitable wiring metal layer) can be formed in each hole 130 and on the bottom surface 193 of each trench 120 such that the top surface 192 of the metal layer 160 is not co-planar with the top surface 191 of the dielectric layer 110, thereby creating the wires 180 and connecting vias 170 (310, see FIGS. 1 and 2 and detailed discussion below). Specifically, the metal layer 160 can be formed such that the difference in height 199 between the top surface 191 of the dielectric layer 110 and the top surface 192 of the metal layer 190 is, for example, between approximately 10% and 30% the overall thickness of the metal layer 190 and, preferably, approximately 20% the thickness of the metal layer 190. Thus, if the metal layer 190 is to be formed with a thickness of approximately 3000 Angstroms, the difference in height 199 between the top surface 191 of the dielectric layer 110 and the top surface 192 of the metal layer 190 should be between 300 and 1000 Angstroms and, preferably, about 600 Angstroms.

An insulating cap layer 190 can then be formed (e.g., conformally deposited by physical vapor deposition (PVD), chemical vapor deposition (CVP), or other suitable technique)) on the dielectric layer 110 and the metal layer 160 (i.e., above the wires 180) (312). This insulating cap layer 190 can comprise a different dielectric material than that used for the dielectric layer 110 and, specifically, can comprise any suitable insulating material that exhibits high atomic diffusion resistance (i.e., an insulating diffusion barrier material that exhibits low atomic diffusivity). For example, the insulating cap layer 190 can have a thickness ranging, for example from 200-2000 Angstroms and can comprise a silicon nitride layer, a silicon oxynitride layer, a silicon carbide layer, a silicon carbon oxide layer, etc.

Next, a second dielectric layer 115 can be formed (e.g., deposited and planarized, if necessary, to form a level surface 116) above the cap layer 190 (314, see the resulting structures shown in FIGS. 1 and 2). This second dielectric layer 115 can comprise either the same interlayer dielectric material as the first dielectric layer 110 (e.g., a silicon dioxide (SiO₂) layer) or a different interlayer dielectric material. Once the second dielectric layer 115 is deposited, the above described process steps 306-314 can be repeated to form additional wiring levels, as necessary (316).

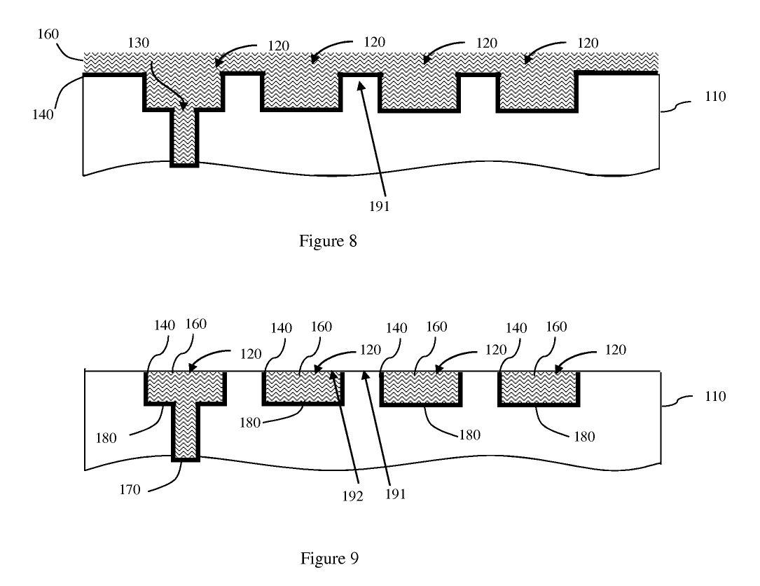

The above-mentioned process 310 of forming a metal layer 160 within each trench 120 such that the top surface 192 of each metal layer 160 (i.e., the top surface of each resulting wire 180) is not co-planar with the top surface 191 of the dielectric layer 110 can be accomplished, for example, by first forming a metal layer 160 on the dielectric layer 110 such that it fills each trench 120 and hole 130 and further such that it extends over the top surface 191 of the dielectric layer 110. For example, a relatively thin seed layer (not shown) can be deposited onto the diffusion barrier liner 140 (e.g., by physical vapor deposition (PVD), chemical vapor deposition (CVP) or any other known and suitable technique) and used during a conventional electroplating process to deposit the wiring metal layer 160 into the holes 130 (i.e., via openings) and trenches 120 (i.e., wiring grooves) (see FIG. 8). This metal layer 160 can then be planarized (e.g., by chemical mechanical planarization (CMP)) such that excess wiring material is removed from the top surface 191 of the dielectric layer 110. As a result of this CMP process, a discrete metal layer 160 remains in each trench 120 and the top surface 192 of the metal layer 160 will be essentially co-planar with the top surface 191 of the dielectric layer 110 (see FIG. 9). Then, either the dielectric layer 110 or the metal layer 160 within each trench 120 can be selectively recessed (311a-b) to achieve the desired difference in height 199 between the top surface 191 of the dielectric layer 110 and the top surface 192 of the metal layer 160.

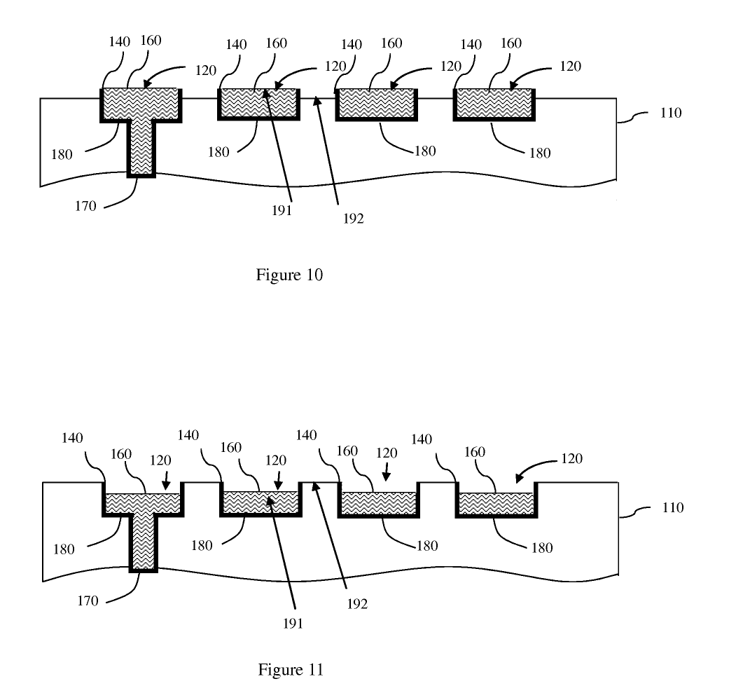

For example, the dielectric layer 110 can be selectively recessed such that the top surface 191 of the dielectric layer 110 is below the top surface 192 of the metal layer 160 (311a, see FIG. 10). If the difference in height 199 between the top surfaces 191 and 192 is to be approximately 10% and 30% the thickness of the metal layer 190 and if the metal layer 190 has a thickness of approximately 3000 Angstroms, the top surface 191 of the dielectric layer can be recess approximately 300 to 1000 Angstroms below the top surface 192 of the metal layer 160. Various etching techniques can be used to selectively recess the dielectric layer 110 over the metal layer 160, including, but are not limited to the following: a diluted hydrofluoric acid (HF) etch process, a plasma etch process using hydrogen (H₂) gas, a dry perfluorocarbon (PFC) reactive ion etch (RIE) process, etc. As a result of this process, a vertical surface 194 on the cap layer 190 in the wiring structure 100, as shown in FIG. 1, will physically prevent metal ion migration from the top surface 192 of the metal layer 160 onto the adjacent top surface 191 of the dielectric layer 110 at an interface between the dielectric layer 110 and the cap layer 190.

Alternatively, the metal layer 160 in each trench 120 can be selectively recessed such that the top surface 191 of the dielectric layer 110 is above a top surface 192 of the metal layer 160 (311b, see FIG. 11). It should be understood that, in this embodiment, previous processing steps should be performed taking into account the desired final thickness of the metal layer 160. For example, if the difference in height 199 between the top surfaces 191 and 192 is to be approximately 10% and 30% the thickness of the metal layer 190 and if the metal layer 190 should have a thickness of approximately 3000 Angstroms, then previous processes (e.g., trench etch and planarization) should be performed such that the metal layer 160 has a thickness of approximately 3300 to 4000 Angstroms before it is selectively recessed. Various etching techniques can be used to selectively recess the metal layer 160 over the dielectric layer 110. For example, with a copper (Cu) metal layer, such techniques can include, but are not limited to the following: a diluted sulfuric acid (H₂SO₄) and hydrogen peroxide (H₂O₂) solution etch process or a controlled oxygen (O₂) plasma etch process followed by a diluted hydrofluoric acid (HF) etch process), etc. As a result of this process, a vertical surface 195 on the dielectric layer 110 in the wiring structure 100, as shown in FIG. 2, will physically prevent metal ion migration from the top surface 192 of the metal layer 160 onto the adjacent top surface 191 of the dielectric layer 110 at an interface between the dielectric layer 110 and the cap layer 190.

It should be understood that any other suitable technique for either under-filling or over-filling trenches 130 with metal layer 160 at process 310 could alternatively be used.

An integrated circuit chip with the above-described wiring structure can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should be understood that the corresponding structures, materials, acts, and equivalents of all means or step plus function elements in the claims below are intended to include any structure, material, or act for performing the function in combination with other claimed elements as specifically claimed. Additionally, it should be understood that the above-description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated. Well-known components and processing techniques are omitted in the above-description so as to not unnecessarily obscure the embodiments of the invention.

Finally, it should also be understood that the terminology used in the above-description is for the purpose of describing particular embodiments only and is not intended to be limiting of the invention. For example, as used herein, the singular forms “a”, “an” and “the” are intended to include the plural forms as well, unless the context clearly indicates otherwise. Furthermore, as used herein, the terms “comprises”, “comprising,” and/or “incorporating” when used in this specification, specify the presence of stated features, integers, steps, operations, elements, and/or components, but do not preclude the presence or addition of one or more other features, integers, steps, operations, elements, components, and/or groups thereof.

Therefore, disclosed above are embodiments of an improved integrated circuit wiring structure configured to prevent migration of wiring metal ions (e.g., copper (Cu+) ions in the case of a copper interconnect scheme) onto the surface of an interlayer dielectric material. Specifically, the top surfaces of wires and the top surface of a dielectric layer within which the wires sit are not co-planar. Thus, the interfaces between the wires and an insulating cap layer and between the dielectric layer and the same cap layer are also not co-planar. Such a configuration physically prevents migration of wiring metal ions from the top surface of the wires onto the top surface of the dielectric layer at the interface between the dielectric layer and cap layer and, thereby prevents time dependent dielectric breakdown (TDDB) and eventual device failure. Also disclosed herein are embodiments of a method of a forming such an integrated circuit wiring structure.

What is claimed is:

1. A wiring structure comprising:
a dielectric layer;
a trench extending vertically into said dielectric layer from a top surface of said dielectric layer;
a metal layer in said trench, wherein a top surface of said metal layer is not co-planar with said top surface of said dielectric layer; and
an insulating cap layer on said top surface of said dielectric layer and said top surface of said metal layer.

2. The wiring structure of claim 1, said dielectric layer comprising a different dielectric material than said cap layer.

3. The wiring structure of claim 1, said dielectric layer comprising an oxide layer and said cap layer comprising a nitride layer.

4. The wiring structure of claim 1, said metal layer comprising copper.

5. The wiring structure of claim 1, wherein, relative to a bottom surface of said trench, said top surface of said dielectric layer is below said top surface of said metal layer such that a vertical surface of said cap layer physically prevents metal ion migration from said top surface of said metal layer onto said top surface of said dielectric layer.

6. The wiring structure of claim 1, wherein, relative to a bottom surface of said trench, said top surface of said dielectric layer is above said top surface of said metal layer such that a vertical surface of said dielectric layer physically prevents metal ion migration from said top surface of said metal layer onto said top surface of said dielectric layer.

7. The wiring structure of claim 1, further comprising a diffusion barrier layer lining said trench.

8. A method of forming a wiring structure, said method comprising:
forming a trench extending vertically into a dielectric layer from a top surface of said dielectric layer;
forming a metal layer in said trench such that a top surface of said metal layer is not co-planar with said top surface of said dielectric layer; and
forming an insulating cap layer on said top surface of dielectric layer and said top surface of said metal layer.

9. The method of claim 8, said dielectric layer comprising a different dielectric material than said cap layer.

10. The method of claim 8, said dielectric layer comprising an oxide layer and said cap layer comprising a nitride layer.

11. The method of claim 8, said metal layer comprising copper.

12. The method of claim 8, further comprising, before said forming of said metal layer, lining said trench with a diffusion barrier layer.

13. A method of forming a wiring structure, said method comprising:
forming a trench extending vertically into a dielectric layer from a top surface of said dielectric layer;
forming a metal layer on said dielectric layer such that said metal layer fills said trench;
planarizing said metal layer such that said metal layer remains only in said trench and a top surface of said metal layer is planar with said top surface of said dielectric layer;
recessing said dielectric layer such that said top surface of said dielectric layer is below said top surface of said metal layer; and
forming an insulating cap layer on said top surface of said dielectric layer and said top surface of said metal layer.

14. The method of claim 13, wherein a vertical surface of said cap layer physically prevents metal ion migration from said top surface of said metal layer onto said top surface of said dielectric layer.

15. The method of claim 13, said dielectric layer comprising a different dielectric material than said cap layer.

16. The method of claim 13, said dielectric layer comprising an oxide layer and said cap layer comprising a nitride layer.

17. The method of claim 13, said metal comprising copper.

18. The method of claim 13, further comprising, before said forming of said metal layer, forming a diffusion barrier layer lining said trench.

19. A method of forming a wiring structure, said method comprising:
forming a trench extending vertically into a dielectric layer from a top surface of said dielectric layer;
forming a metal layer on said dielectric layer such that said metal layer fills said trench;
planarizing said metal layer such that said metal layer remains only in said trench and a top surface of said metal layer is planar with said top surface of said dielectric layer;
recessing said metal layer such that said top surface of said dielectric layer is above said top surface of said metal layer; and
forming an insulating cap layer on said top surface of said dielectric layer and said top surface of said metal layer.

20. The method of claim 19, wherein a vertical surface of said dielectric layer physically prevents ion migration from said top surface of said metal layer onto said top surface of said dielectric layer.

21. The method of claim 19, said dielectric layer comprising a different dielectric material than said cap layer.

22. The method of claim 19, said dielectric layer comprising an oxide layer and said cap layer comprising a nitride layer.

23. The method of claim 19, said metal comprising copper.

24. The method of claim 19, further comprising, before said forming of said metal layer, forming a diffusion barrier layer lining said trench.
